(19) United States
(12) Patent Application Publication
(10) Pub. No.: US 2008/0219399 A1
(43) Pub. Date: Sep. 11, 2008

(54) Frequency Divider With Symmetrical Output

(76) Inventor: Kevin R. Nary, Westlake Village, CA (US)

Correspondence Address: SoCAL IP LAW GROUP LLP, 310 N. WESTLAKE BLVD. STE 120, WESTLAKE VILLAGE, CA, 91362, US

(21) Appl. No.: 11/683,381

(22) Filed: Mar. 7, 2007

(51) Int. Cl. H03K 21/10

(52) U.S. Cl. 377/47; 708/844

(57) ABSTRACT

There is disclosed an apparatus for dividing the frequency of an input signal by an integer N. First and second means may divide the frequency of the input signal by a factor of N and then by a factor of 2. An output of the first means and an output of the second means may be combined by an exclusive OR gate. Third means may be used to control the relative phase of the outputs from the first and second means such that the output from the first means and the output of the second means differ in phase by one-quarter cycle or 90 degrees.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

1. Field

This disclosure relates to circuitry for dividing the frequency of a signal.

2. Description of the Related Art

Frequency dividers are used in frequency synthesizers for many applications and in test and measurement equipment. Some application require a frequency divider to provide a symmetrical output with 50% duty factor, even when the frequency is divided by an odd integer.

### DESCRIPTION OF THE DRAWINGS

FIG. 1A is a block diagram of a frequency divider.

FIG. 1B is a block diagram of a counter phase control circuit.

FIG. 2 is a timing diagram for the frequency divider of FIG. 1.

FIG. 3 is a block diagram of a frequency divider.

FIG. 4 is a timing diagram for the frequency divider of FIG. 3.

FIG. 5 is a block diagram of a frequency divider.

FIG. 6 is a timing diagram for the frequency divider of FIG. 5.

FIG. 7 is a block diagram of a frequency divider.

FIG. 8 is a block diagram of a frequency divider.

### DETAILED DESCRIPTION

Throughout this description, the embodiments and examples shown should be considered as exemplars, rather than limitations on the apparatus and methods disclosed or claimed.

Description of Apparatus

Throughout the drawings, elements have been assigned three digit reference designators where the most significant digit is the drawing number and the two least significant digits define an element. Common elements having the same function in multiple figures will have reference designators with the same least significant digits. The description of common elements will not be repeated for each and every figure. An element that is not described in conjunction with a figure may be presumed to have the same function as that described for the counterpart element in a preceding figure. Reference designators used in timing diagrams have the same least significant digits as the corresponding signal line or element in the preceding figure.

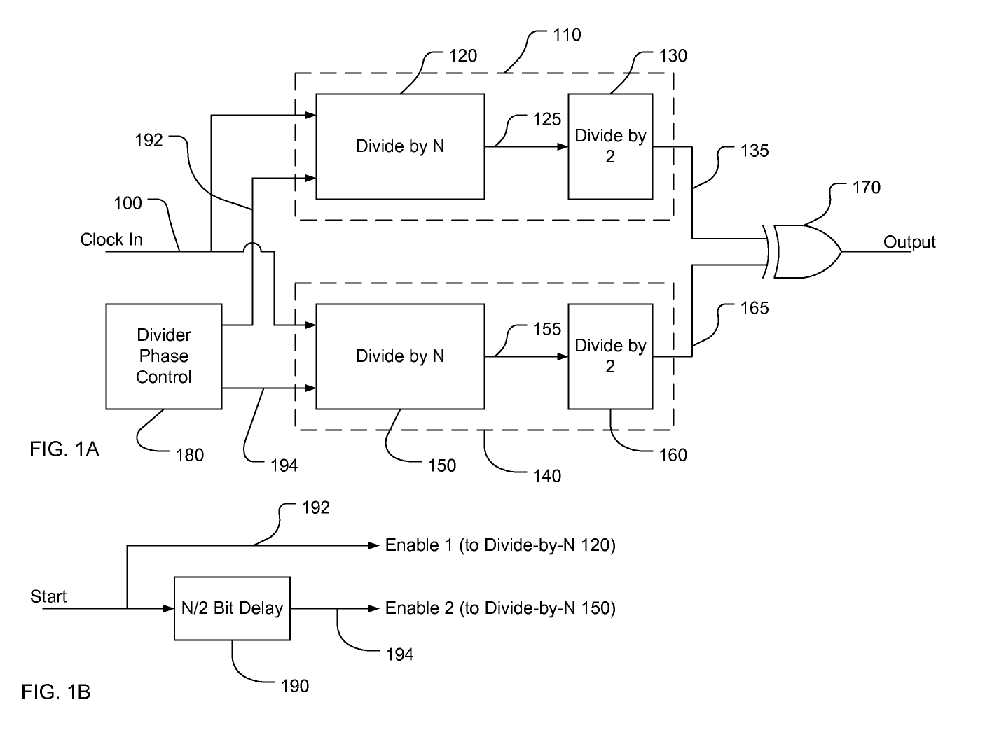

Referring now to FIG. 1A, a frequency divider may be comprised of a first means 110 for dividing the frequency of an input clock signal (Clock In) by N and then by 2 to provide a first divided signal 135, second means 140 for dividing the frequency of the input clock signal by N and then by 2 to provide a second divided signal 165, an exclusive OR logic function 170 to combine the first and second divided signals 135/165, and third means 180 to control the relative phase of the first and second divided signals 135/165. The first means 110 may be comprised of a first divide-by-N circuit 120 and a first divide-by-2 circuit 130. The first divide-by-N circuit 120 may be implemented by an up-counter, a down-counter, a circular shift register, or other circuit that can provide the divide-by-N function. The first divide by N circuit 120 may provide a first 1/N signal 125 every N clock cycles. The first divide-by-2 circuit 130 may be a T flip-flop or other circuit. The output of the first divide-by-2 circuit 130 is the first divided signal 135, which has a 50% duty factor and a frequency equal to the frequency of the input clock signal 100 divided by 2N.

The second means 140 may be comprised of a second divide-by-N circuit 150 and a second divide-by-2 circuit 160. The second divide by N circuit 150 may provide a second 1/N signal 125 every N clock cycles. The second divide-by-N circuit 150 may be implemented as described for the first divide-by-N circuit 120. The first divide-by-N circuit 120 and the second divide-by-N circuit 150 may or may not be implemented in the same manner. The output of the second divide-by-2 circuit 160 is the second divided signal 165, which has a 50% duty factor and a frequency equal to the frequency of the input clock signal 100 divided by 2N.

The first divided signal 135 and the second divided signal 165 are both symmetrical signals having 50% duty factor and a frequency equal to the input clock frequency divided by 2N. The third means controls the relative phase of the first and second divided signals 135/165 such that the first and second divided signals 135/165 differ in phase by one-quarter cycle or 90 degrees. Combining the first divided signal 135 and the second divided signal 165 with exclusive OR function 170 provides an output signal having 50% duty factor and a frequency equal to the frequency of the input clock signal 100 divided by N.

The first means 110 and the second means 140 may be synchronous circuits where all internal and external signals change in response to a rising edge or a falling edge of a clock signal. All of the timing diagrams in this description assume the circuits are responsive to the rising edge of the clock.

The frequency divider, including first means 110, second means 140, third means 180, and exclusive OR function 170 may be implemented by software instructions executed on a processor. The frequency divider may be implemented in hardware or a combination of hardware, firmware and software. The frequency divider hardware may include one or more of logic arrays, digital circuits, field programmable gate arrays (FPGAs), application specific integrated circuits (ASICs), programmable logic devices (PLDs) and programmable logic arrays (PLAs).

The frequency divider may be implemented on a single integrated circuit chip. For high speed applications, the frequency divider may be implemented using Silicon, Silicon-Gemanium, Gallium Arsenide, Indium Phosphide, or other integrated circuit technology. The frequency divider may be implemented with any static logic family, including, but not limited to, conventional static complementary metal-oxide-semiconductor (CMOS) logic, differential current-mode logic (CML) using field-effect or bipolar devices, and emitter-coupled logic (ECL) bipolar logic families including positive emitter coupled logic (PECL) and low voltage positive emitter coupled logic (LVPECL).

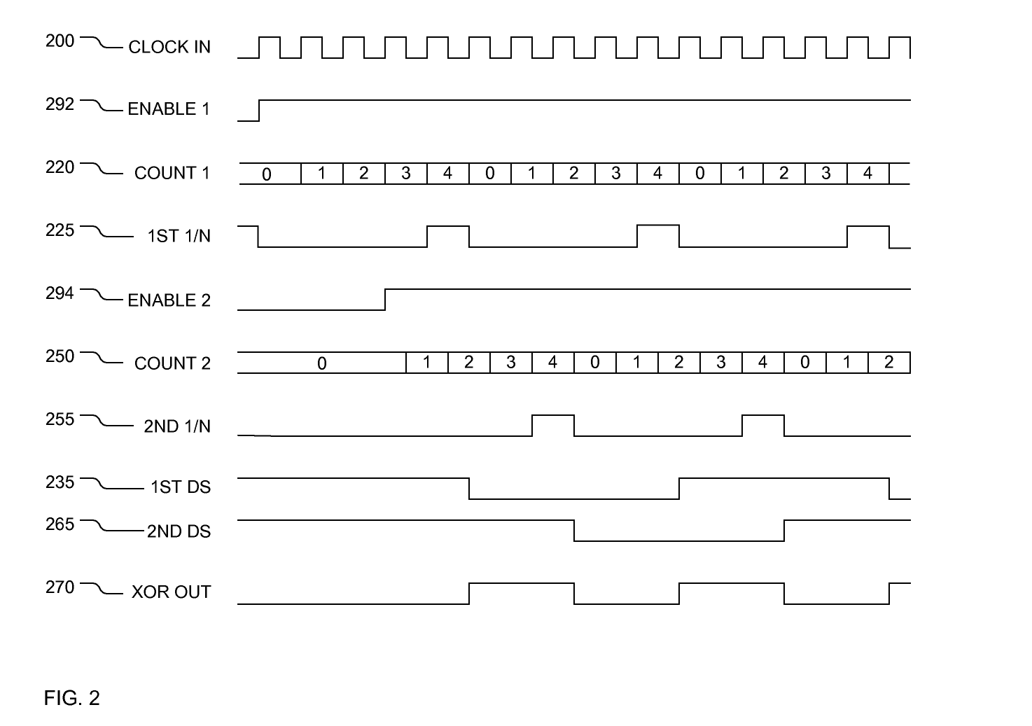

FIG. 1B is a block diagram of an exemplary divider phase control circuit simply comprised of an N/2 bit delay circuit which may be a shift register. The operation of this circuit will be described in conjunction with FIG. 2.

FIG. 2 is a timing diagram of the frequency divider of FIG. 1, where N equals five. Reference designators in FIG. 2 can be correlated to elements or signals of FIG. 1 by simply changing the first digit of the reference designator to “1”. For the purposes of FIG. 2, the divide-by-N circuits (120, 150 in FIG. 1) are assumed to be up-counters counting from “0” to “4”. The Enable 2 signal (line 294) is delayed with respect to the Enable 1 signal (line 292) by the divider phase control circuit (190 in FIG. 1B) such that the second divide-by-N counter (line 250) starts counting 2.5 cycles of Clock 1 (line 202) after the first divide-by-N counter starts (line 220).

The first divided signal (line 230, labeled “1^{st} DS) and the second divided signal (line 260, labeled “2^{nd} DS) are square waves with 50% duty factor and a frequency equal to the frequency of the input clock (line 200) divided by 2N (2×5=10 in this example). The output signal 270 from the exclusive OR gate has 50% duty cycle and a frequency equal to the frequency of the input clock (line 200) divided by N (5 in this example).

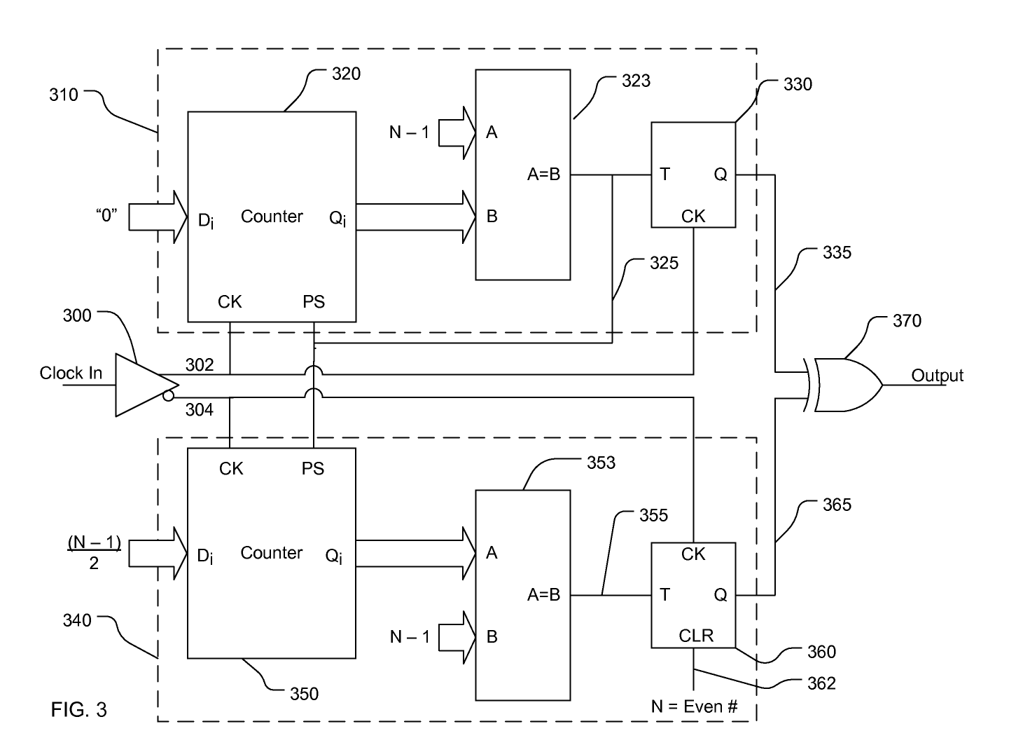

FIG. 3 is a block diagram of another frequency divider. The first means 310 for dividing the frequency of an input clock signal by N and then by 2 may be comprised of a counter chain including a first up-counter 320, a first comparator 323, and a first T flip flop 330. The first up-counter 320 receives a clock input CK, a preset input PS, and parallel data inputs Di, and provides parallel count outputs Qi, where “i” is the number of bits in the counter. The count outputs Qi increment by one count on the active edge of the clock signal CK when PS is logical “0”. When PS is logical “1”, the Qi outputs are set equal to the Di inputs on the active edge of clock signal CK.

The first T flip-flop 330 is a known circuit where the output Q changes state in response to a clock if the T input is logical “1”, and holds the previous state if the T input is logical “0”. A T flip-flop may be implemented as a J-K flip flop with the J and K inputs connected together to form the T input.

The first comparator 323 compares the Qi outputs from the first counter 320 to the value N−1. The output 325 from the first comparator 323 feeds the PS input on the first counter 320 such that the first counter 320 is preset to zero on the clock cycle after the Qi outputs reach a value of N−1. Thus the first counter 320 counts cyclically between zero and N−1. The output 325 from the first comparator 323 also feeds the T input of the first toggle flip-flop 330.

The second means 340 for dividing the frequency of an input clock signal by N and then by 2 may be comprised of a second counter chain including a second up-counter 350, a second comparator 353, and a second T flip flop 360. The functionality of the second counter 350 may be the same as that described for the first counter 320. The second comparator 353 compares the Qi outputs from the second counter 350 to the value N−1. The output 355 from the second comparator 353 drives the T input of the second toggle flip-flop 360. The output 325 from the first comparator 323 drives the PS input of the second counter 350, and causes the second counter 350 to be preset to a value of (N−1)/2. Using the same signal 325 to preset the first counter 320 and the second counter 350 to different values is an implementation of the third means to control the relative phase of the first and second divided signals 335/365.

The second T flip-flop 360 may have an input 362, labeled “CLR”, to inhibit toggling and thus force the second divided signal 365 to a fixed logical state where the first divided signal 365 is continuously either “0” or “1”. With the toggling of the second T flip-flop 360 inhibited, the output for the exclusive OR gate 370 will have the same frequency as the first divided signal 335. In this manner, the first means 310 can be used to divide the input clock frequency by an even number N. When dividing by an even number, the first comparator 323 may compare the Qi outputs from the first counter 320 to the value N/2-1.

A buffer 300 may accept the input clock signal (Clock In) and may provide a first clock 302 and a second clock 304. The second clock 304 may be the complement, or inverse, of the first clock 302. The first means 310 may be responsive to the first clock 302. The second means 340 may be responsive to the second clock 304, as shown. Alternately, the first means 310 may be responsive to a rising edge of a clock and the second means may be responsive to the falling edge of the same clock. Additionally, the first means 310 and the second means 340 may be implemented with circuitry that requires a differential clock. In this case, the polarity of the clock signals would be reversed for the first means 310 and the second means 340.

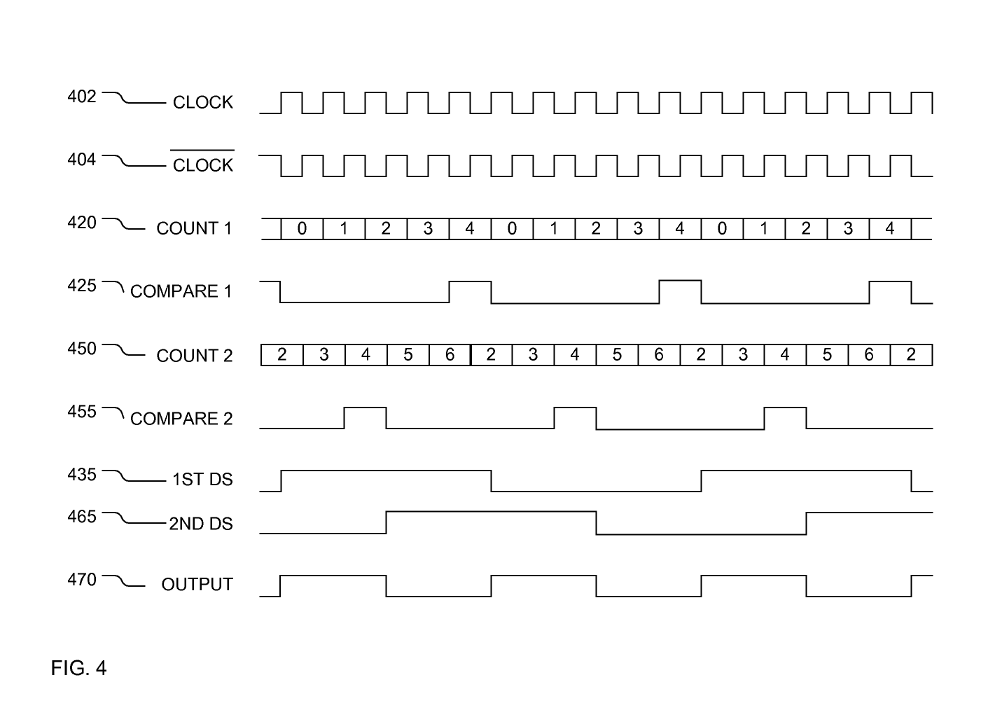

FIG. 4 is a timing diagram for the frequency divider shown in FIG. 3 for the case N=5. Note that, while the first up-counter (line 420) counts cyclically between 0 and 4, the second up-counter (line 450) counts cyclically between 2 and 6. Since the second counter is responsive to the complementary clock signal (line 404), the second counter (line 450) is preset to “2” one-half clock cycle before the first counter (line 420) is preset to “0”.

Note that the rising edge of the output 470 is synchronous with the rising edge of the first clock 402, and the falling edge of the output 470 is synchronous with the rising edge of the complementary second clock 404. Thus the output 470 will have precisely 50% duty cycle if the first and second clocks 402 and 404 are complementary and have 50% duty cycle. In cases where a precise 50% duty cycle is desired for the output 470, additional circuitry may be required to ensure the input clock also has a precise 50% duty cycle. The output 470 will also have a 50% duty cycle if the rising edge of the second clock 404 occurs precisely at the mid-point between successive rising edges of the first clock 402.

Any error in the phase or duty cycle of the clock signals will not be multiplied when the frequency is divided. For example, assume that the first and second clocks have a frequency of 1 MHz but are asymmetric by 100 nanoseconds (ns) such that the first clock 402 is “0” for 450 ns and “1” for 550 ns and the second clock 404 is the complement of the first clock 402. After dividing by seven, the output 470 will have a period of 7 microseconds (us) but will also be asymmetric by 100 ns (logic “0” for 3.450 and Logic “1” for 3.550 us).

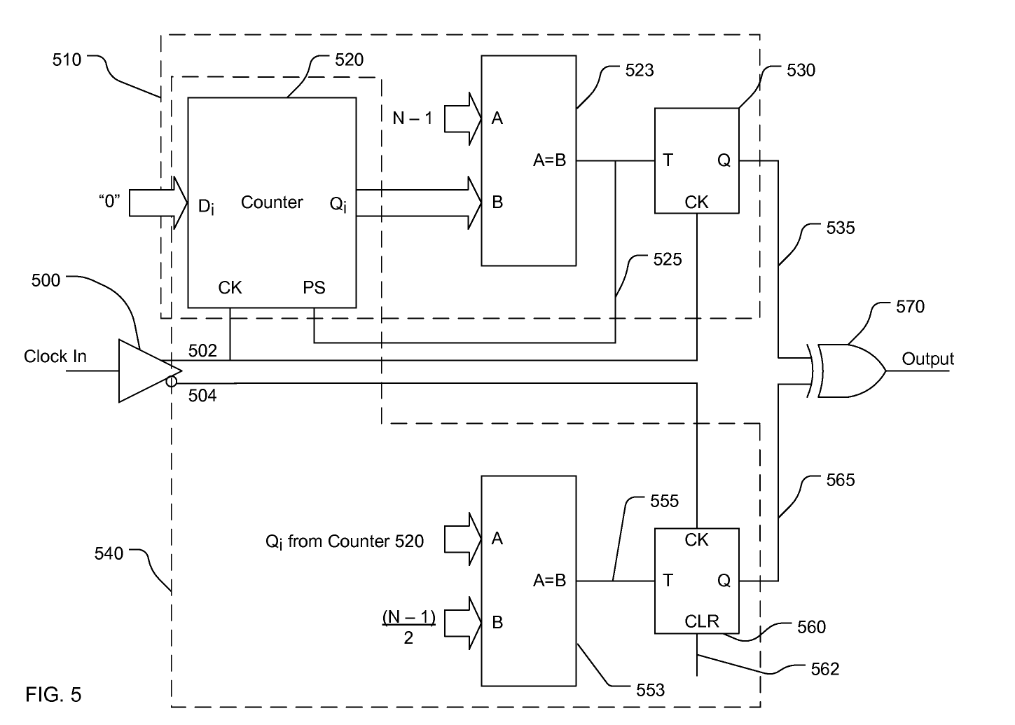

FIG. 5 is a block diagram of another frequency divider. The first means 510 for dividing an input frequency by N and then by 2 may be a first counter chain comprised of a first up-counter 520, a first comparator 523, and a first T flip-flop 530, all of which function as previously described in conjunction with FIG. 3. The second means 540 for dividing an input frequency by N and then by 2 may be a second counter chain comprised of the first up-counter 520 (shared with the first means), a second comparator 553, and a second T flip-flop 560. The second comparator 553 compares the Qi outputs from the first counter 520 with the value (N−1)/2. In this embodiment, the third means to control the relative phase of the first and second divided signals is implemented by toggling the first T flip-flop 530 when the first counter 520 has reached the maximum count value, and by toggling the second T flip-flop 560 when the first counter 520 is half way between its minimum and maximum values.

The frequency divider of FIG. 5 does not include a second counter and thus has less circuitry than the frequency divider previously shown in FIG. 3. However, while the first clock 502 drives the first counter 520 and the first toggle flip-flop 530, the second clock 504 only drives the second toggle flip-flop 560. The unequal loading on the first and second clocks may complicate or preclude achieving a precisely 50% duty cycle for the output 570 since the higher-loaded first clock may suffer a delay or phase shift with respect to the second clock. For applications requiring high precision, the additional circuitry required to maintain symmetric clock loading may be justified.

Returning briefly to FIG. 3, the first means 310 and the second means 340 may be symmetrically arranged on an integrated circuitry chip such that all delays in the circuitry are equalized.

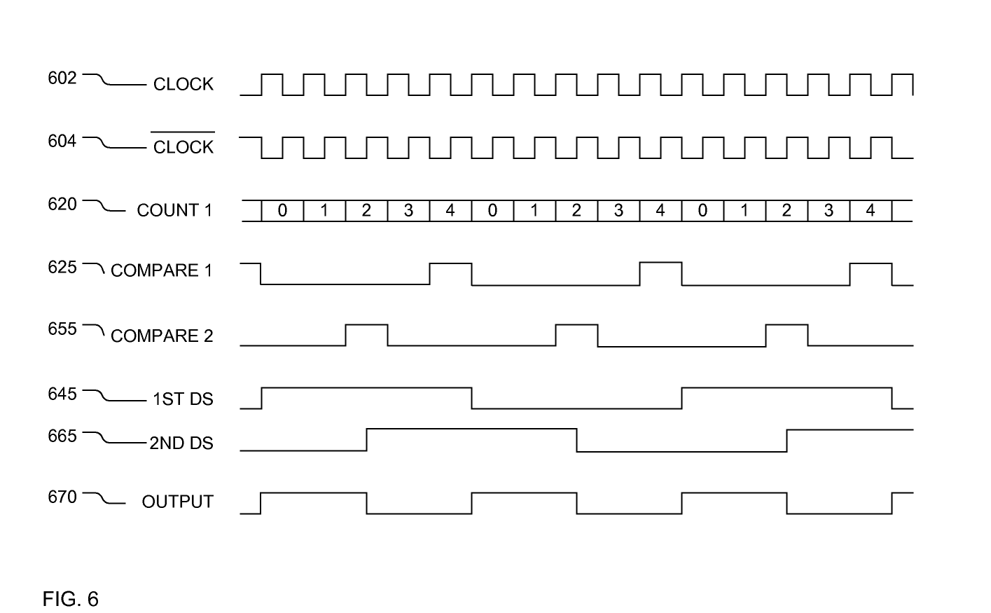

FIG. 6 is a timing diagram of the frequency divider shown in FIG. 5.

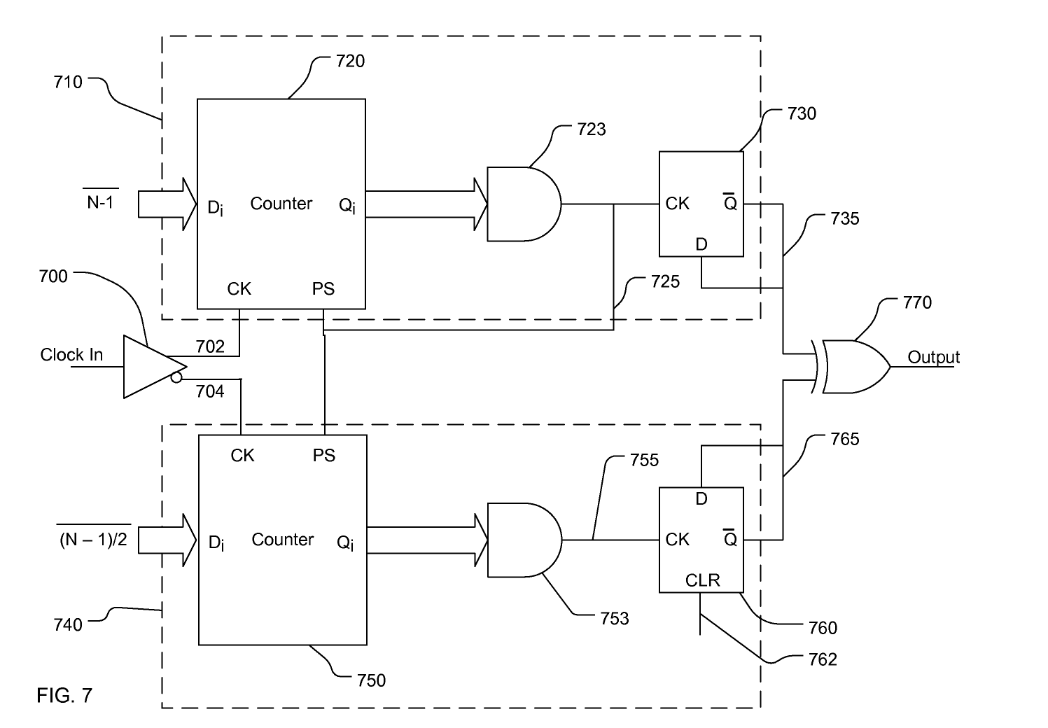

FIG. 7 is a block diagram of another frequency divider. The first means 710 for dividing a frequency by N and then by 2 may be a counter chain comprised of a first counter 720, an AND gate 723, and a first T flip-flop 730. The AND gate 723 provides an output 725 that is logical “1” when all of the Qi outputs from the first counter 720 are also logical “1”. The output 725 is applied to the PS input of the first counter 720 and causes the first counter 720 to be preset to the complement of N−1 (which is equal to 2ⁱ−N, where “i” is the number of bits in the counter). For example, assume the first counter is a four-bit counter and N=5. In this case, the first counter will count cyclically between 11 and 15. The second means 740 may operate in a similar manner, except that the second counter 750 may be preset to the complement of (N−1)/2.

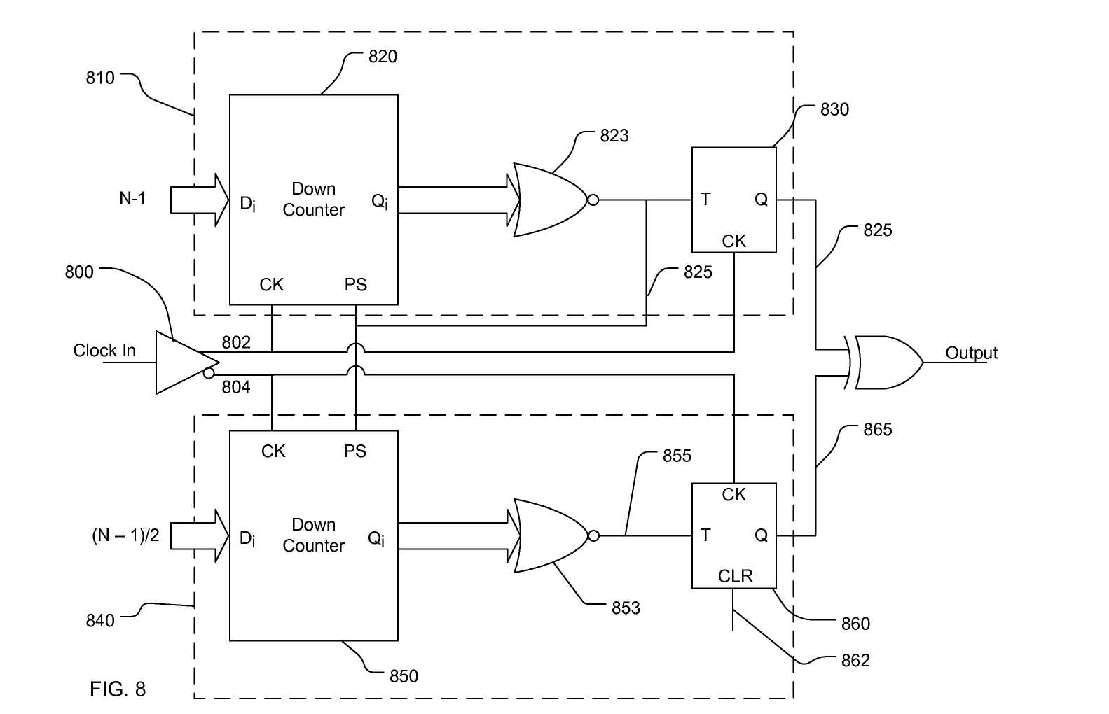

In contrast to FIG. 3 and FIG. 5, FIG. 7 illustrates that toggle flip-flops 730 and 760 may be implemented as D flip-flops. Each flip-flop has a D input and a not-Q output that are connected such that each flip-flop changes state, or toggles, on every clock input. The clock inputs to the D flip-flops 730 and 760 are provided by the outputs from gates 723 and 755, respectively. Note that the toggle flip-flops of FIG. 3, FIG. 5, FIG. 7 and FIG. 8 may be implemented with J-K flip-flops, D flip-flops, or other circuitry to provide divide-by-2 functionality.

FIG. 8 is a block diagram of another frequency divider closely related to the frequency divider shown in FIG. 7. The first means 810 for dividing a frequency by N and then by 2 may be a counter chain comprised of a first down counter 820, a NOR gate 823, and a first T flip-flop 830. The NOR gate 823 provides an output 825 that is logical “1” when all of the Qi outputs from the first counter 820 are logical “0”. The output 825 is applied to the PS input of the first counter 820 and causes the first counter 820 to be preset to N−1. Thus the first counter 820 may count cyclically between N−1 and zero in reverse order. The second means 840 may operate in a similar manner, except that the second counter 850 may be preset to (N−1)/2.

Any of the previously described frequency dividers and the subsequently described frequency division process may be incorporated within frequency synthesizers or in frequency counters for a variety of applications.

Description of Processes

Referring back to FIG. 1A, the block diagram of a frequency divider may also be used to understand a process for dividing the frequency of an input signal by a factor N. The process includes dividing the frequency of the input signal by a factor of N and then by a factor of 2 (block 110) to provide a first divided signal 135, and dividing the frequency of the input signal by a factor of N and then by a factor of 2 (block 140) to provide a second divided signal 165. At block 180, the relative phase of the first divided signal 135 and the second divided signal 165 are controlled such that the phase of the first divided signal 135 and the phase of the second divided signal 165 differ by one-quarter cycle or 90 degrees. At block 170, the first divided signal 135 and the second divided signal 165 are combined using exclusive OR logic to provide an output signal having 50% duty factor and a frequency equal to the frequency of the input clock signal 100 divided by N.

Closing Comments

The foregoing is merely illustrative and not limiting, having been presented by way of example only. Although examples have been shown and described, it will be apparent to those having ordinary skill in the art that changes, modifications, and/or alterations may be made.

Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

For means-plus-function limitations recited in the claims, the means are not intended to be limited to the means disclosed herein for performing the recited function, but are intended to cover in scope any means, known now or later developed, for performing the recited function.

As used herein, whether in the written description or the claims, the terms “comprising”, “including”, “carrying”, “having”, “containing”, “involving”, and the like are to be understood to be open-ended, i.e., to mean “including but not limited to”. Only the transitional phrases “consisting of” and “consisting essentially of”, respectively, are closed or semi-closed transitional phrases with respect to claims.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

As used herein, “and/or” means that the listed items are alternatives, but the alternatives also include any combination of the listed items.

It is claimed:

1. An apparatus for dividing an input frequency by an odd integer N, comprising:
a first counter chain for dividing the input frequency by N and then by two to provide a first divided signal
a second counter chain for dividing the input frequency by N and then by two to provide a second divided signal
a phase control circuit to cause a phase of the first divided signal and a phase of the second divided signal to differ by 90 degrees
an exclusive OR gate to combine the first divided signal and the second divided signal to provide an output signal.

2. The apparatus for dividing an input frequency by an odd integer N of claim 1, wherein the phase control circuit delays a count enable signal to the second counter chain with respect to a count enable signal to the first counter chain.

3. The apparatus for dividing an input frequency by an odd integer N of claim 1, wherein the phase control circuit uses an output of the first counter chain to preset the second counter chain to a predetermined number.

4. The apparatus for dividing an input frequency by an odd integer N of claim 1, wherein
the first counter chain further comprises
a first counter
a first toggle flip-flop, the first divided signal being an output of the first toggle flip-flop, wherein the first counter and first toggle flip-flop are responsive to a first clock
a first comparator circuit to generate a first reset signal to reset the first counter and to cause the first toggle flip-flop to change state after the first counter has counted for N cycles of the first clock
the second counter chain further comprises
a second toggle flip-flop, the second divided signal being an output of the second toggle flip-flop, wherein the second toggle flip-flop is responsive to a second clock
wherein the second clock is complementary to the first clock.

5. The apparatus for dividing an input frequency by an odd integer N of claim 4, wherein
the second counter chain further comprises a second counter
the second toggle flip-flop changes state every N counts of the second counter
the first reset signal causes the second counter to be preset to a predetermined value every N counts of the first counter.

6. The apparatus for dividing an input frequency by an odd integer N of claim 1, wherein
the first counter chain is responsive to a first clock
the second counter chain is responsive to a second clock, the second clock being complementary to the first clock.

7. The apparatus for dividing an input frequency by an odd integer N of claim 6, wherein the first clock signal and the second clock signal have 50% duty cycle.

8. The apparatus for dividing an input frequency by an odd integer N of claim 7, wherein the loads on the first clock signal and the second clock signal are equal.

9. The apparatus for dividing an input frequency by an odd integer N of claim 1, wherein the first counter chain and the second counter chain are disposed symmetrically on an integrated circuit chip.

10. The apparatus for dividing an input frequency by an odd integer N of claim 4, wherein the second counter chain further comprises
a second comparator circuit to generate a second reset signal when the first counter has counted for (N−1)/2 counts after being reset by the first reset signal
the second reset signal causing the second toggle flip-flop to change state.

11. The apparatus for dividing an input frequency by an odd integer N of claim 1 implemented on a single integrated circuit chip.

12. The apparatus for dividing an input frequency by an odd integer N of claim 1 incorporated in a frequency synthesizer or frequency counter.

13. The apparatus for dividing an input frequency by an odd integer N of claim 1 further comprising
circuit means to force the second divided signal to a fixed logical state
wherein the first counter chain divides the input by an even integer 2N when the second divided signal is in a fixed logic state.

14. A method for dividing an input frequency by an odd integer N, comprising:
forming a first divided signal by dividing the input frequency by N and then by two
forming a second divided signal by dividing the input frequency by N and then by two
controlling the phase of at least one of the first divided signal and second divided signal to cause the phase of the first divided signal and the phase of the second divided signal to differ by 90 degrees
combining the first divided signal and the second divided signal with an exclusive OR function to provide an output signal.

15. The method for dividing an input frequency by an odd integer N of claim 14, wherein
the first divided signal is formed by a first counter chain
the second divided signal is formed by a second counter chain

16. The method for dividing an input frequency by an odd integer N of claim 15, wherein controlling comprises delaying a count enable signal to the second counter chain with respect to a count enable signal to the first counter chain.

17. The method for dividing an input frequency by an odd integer N of claim 15, wherein controlling comprises using a signal from the first counter chain to set the second counter chain to a predetermined value.

18. An apparatus for dividing an input frequency by an odd integer N, comprising:
first means for dividing the input frequency by N and then by two to provide a first divided signal
second means for dividing the input frequency by N and then by two to provide a second divided signal
third means for controlling the phase of the first divided signal and the phase of the second divided signal to differ by 90 degrees
an exclusive OR function to combine the first divided signal and the second divided signal to provide an output signal.

19. The apparatus for dividing an input frequency by an odd integer N of claim 18, wherein the first means and the second means each comprise a divide-by-N circuit selected from the group consisting of a circular shift register, an up-counter, and a down-counter.

20. The apparatus for dividing an input frequency by an odd integer N of claim 19, wherein the first means and the second means each further comprise a T flip-flop.

21. The apparatus for dividing an input frequency by an odd integer N of claim 18, wherein the third means comprises a circuit for delaying an enable signal to the second means with respect to an enable signal to the first means.

22. The apparatus for dividing an input frequency by an odd integer N of claim 18, wherein the third means comprises using a signal from the first means to preset the second means to a predetermined value.

23. The apparatus for dividing an input frequency by an odd integer N of claim 18 further comprising
means to force the second divided signal to a fixed logical state
wherein the first means for dividing divides the input frequency by an even integer 2N when the second divided signal is in a fixed logic state.
